(19) United States
(12) Patent Application Publication
(10) Pub. No.: US 2006/0021736 A1
(43) Pub. Date: Feb. 2, 2006

(54) Pin type heat sink for channeling air flow

(75) Inventor: Thanh Van Tran, Temple City, CA (US)

Correspondence Address: OSTROLENK FABER GERB & SOFFEN, 1180 AVENUE OF THE AMERICAS, NEW YORK, NY, 100368403, US

(73) Assignee: International Rectifier Corporation

(21) Appl. No.: 11/189,641

(22) Filed: Jul. 26, 2005

Related U.S. Application Data
(60) Provisional application No. 60/592,351, filed on Jul. 29, 2004.

(51) Int. Cl. H05K 7/20

(52) U.S. Cl. 165/80.3; 361/704

(57) ABSTRACT

A pin heat sink has a plurality of pins arranged on a base plate. The plurality of pins includes a first plurality of pins arranged to create one or more funnels of air flow directed to one or more hot spots created by electronic or other heat generating devices located beneath the base plate. A set of pins is located above each hot spot. In addition, a plurality of guard pins is located to the exterior of the remainder of the pins and is spaced at closer intervals than the remainder of the pins to limit leakage of air flow outside of the heat sink.

### CROSS-REFERENCE TO RELATED APPLICATION

This application claims the benefit of U.S. Provisional Application No. 60/592,351, filed on Jul. 29, 2004, the entirety of the contents of which are hereby incorporated by reference herein.

### BACKGROUND OF THE INVENTION

1. Field of the Invention

The present invention relates to pin type heat sinks, and more particularly to a heat sink in which the pins are placed to channel the air flow through the heat sink.

2. Description of the Related Art

Heat sinks are commonly used to vent excess heat from electronic devices or other heat generating devices. Typically, a base plate of a heat sink is attached with epoxy or other adhesive to the substrate on which electronic devices or other heat generating devices are mounted and various pins, fins or other elements of the heat sink are arranged on the base plate. Pins, fins or other arranged elements serve to dissipate the excess heat from the electronic or other heat generating devices with the aid of air flow which flows past the arranged elements.

Various methods are already known to more efficiently direct the air flow through the heat sink and therefore dissipate the heat generated by the electronic or other heat generating devices at a faster rate. Among those methods are an air flow directional vane element directing the air flow across the heat sink through the heat dissipating elements, heat radiating fin plates arranged in a generally radial manner, and an annular arrangement of heat radiating fin plates.

The related art, however, fails to suggest an arrangement which deals with known locations of heat concentration or “hot spots” that may be generated by electronic or other heat generating devices.

### BRIEF SUMMARY OF THE INVENTION

In one embodiment of the invention, a heat sink comprises pins arranged in a “funnel” arrangement to direct air flow toward interior regions of a heat sink, and guard pins are also provided at the edges of the heat sink to limit leakage of air through the exterior sides of the heat sink.

Other embodiments of the invention eliminate the interior funnel pin arrangement in the heat sink while retaining guard pins of various sizes.

### BRIEF DESCRIPTION OF THE DRAWINGS

FIG. 1 is a plan view of a conventional staggered pin heat sink.

FIG. 2 is a plan view of a first embodiment of the invention.

FIG. 2A is an enlarged cross-section of a portion of FIG. 2 taken through section lines 2A-2A in FIG. 2

FIG. 3 is a plan view of a second embodiment of the invention.

FIG. 4 is a plan view of a third embodiment of the invention.

### DETAILED DESCRIPTION OF EMBODIMENTS OF THE INVENTION

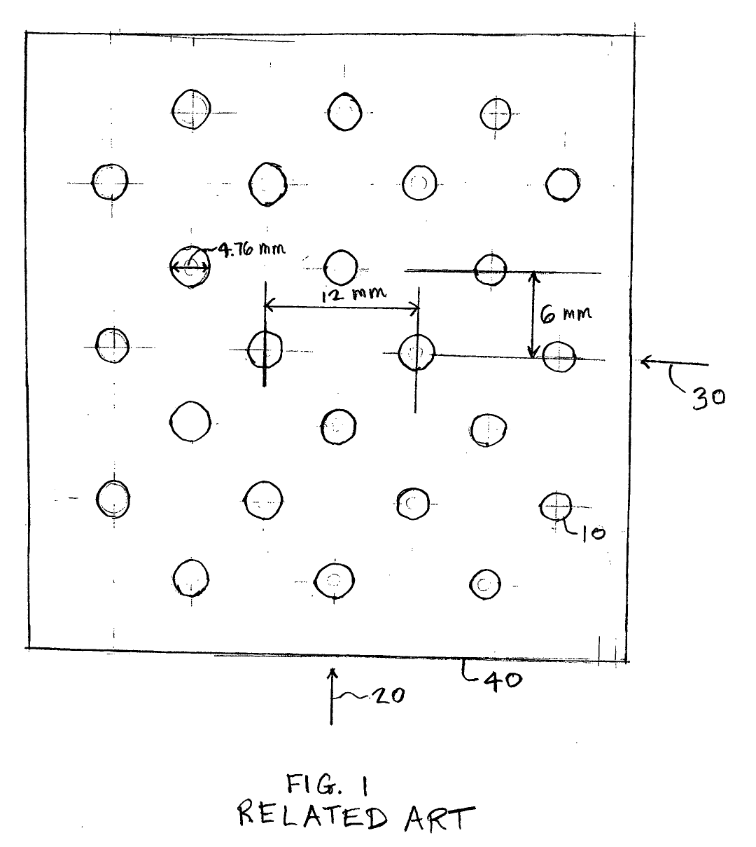

FIG. 1 shows a conventional staggered pin type heat sink. The arrangement of the pins in rows, with the rows being arranged so that individual pins in one row are offset in a horizontal direction, from pins in an adjacent row, allows each pin 10 to be exposed to the air flow, assuming that the air flow is in a direction 20, 30 perpendicular to the edges of the base plate 40, from which the pins 10 extend in a perpendicular direction. If the pins 10 were not staggered, but arranged in aligned rows so that columns of pins were formed from corresponding pins in each row, it can easily be understood that the interior pins would have much less exposure to any air flow in a direction 20, 30 flowing over the base plate 40 than the pins nearest to the edges of the base plate 40.

However, this conventional staggered arrangement pin allows extensive escape of air in a direction perpendicular to the direction of an air flow. In addition, it does not concentrate the air flow in any particular area so as to alleviate any hot spots that may arise as the result of operation of the electronic or other heat generating devices attached to the base plate 40.

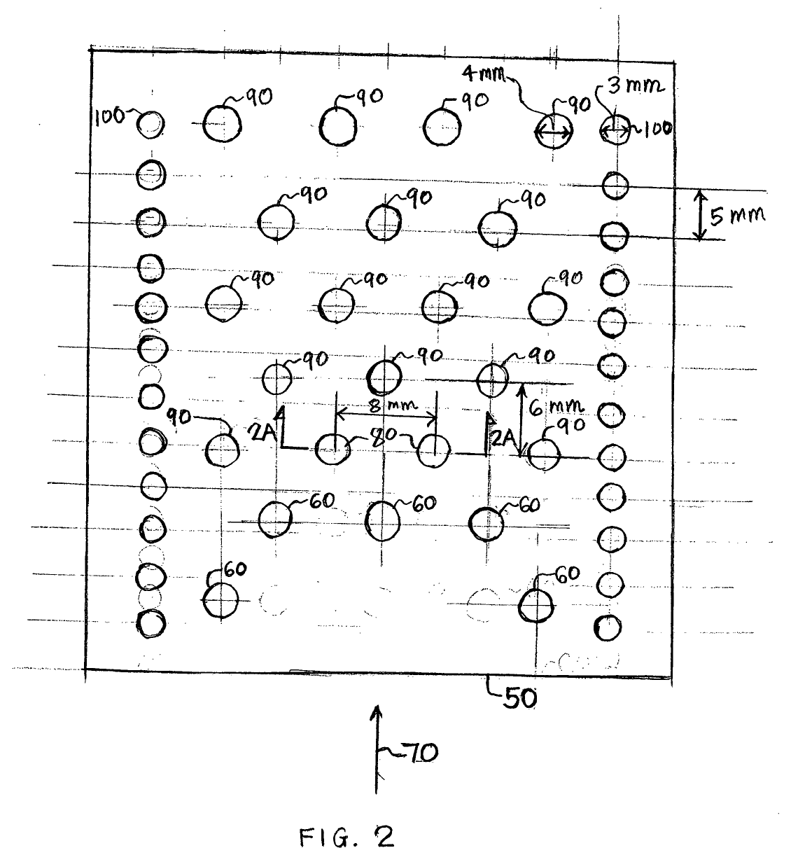

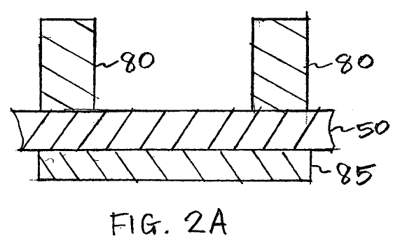

FIG. 2 shows an exemplary first embodiment of the invention. As in the conventional arrangement shown in FIG. 1, there is a base plate 50 and there are pins which act as heat dissipating elements. However, the arrangement of the pins and the types of pins utilized are different than in a conventional arrangement.

FIG. 2 shows pins 60, arranged in a funnel type arrangement, to concentrate an air flow 70 towards center pins 80, which are located over a “hot spot” conducted through the base plate 50 as a consequence of the functioning of the electronic or other heat generating devices beneath base plate 50. In particular, FIG. 2A shows, for example, a semiconductor chip 85 beneath base plate 50, the semiconductor chip 85 being responsible for the previously mentioned “hot spot.” The center pins 80, of course, dissipate the heat generated by the “hot spot” with the aid of the air flow 70 directed toward them by the funnel pins 60. The funnel pins 60, in addition to funneling the air flow 70 towards the center pins 80, also aid in dissipating heat generated by the electronic or other heat generating devices under the area of the base plate 50 in which they are located. However, funnel pins 60 are arranged over the base plate 50 such that the area of the base plate 50 in which the funnel pins 60 are arranged contains less funnel pins 60 than an equal area of the base plate 50 contains of the remainder of the pins. Therefore, it is assumed that the heat to be dissipated in the area of a plate in which they are located is not as great as in other areas of the base plate 50.

Secondary pins 90 are arranged in a conventional staggered pin manner to dissipate heat generated in the upper part of the plate 50. In order to limit the flow of air in directions perpendicular to the air flow 70, guard pins 100 have been placed in two columns, each column being near to an edge of the base plate parallel to the direction of the air flow 70. The guard pins 100, as previously mentioned, limit the flow of air in directions perpendicular to the direction of air flow 70 and, thus, improve the transfer of heat from pins 60, 80 and 90 to the air flow 70. In addition, the guard pins 100 also act as heat dissipating elements transferring heat to the air flow 70. In order to perform the function of limiting the escape of air flow from the sides of the heat sink, the guard pins are spaced more closely to each other than the remainder of the pins. In this embodiment, the guard pins are of smaller diameter than the remainder of the pins to facilitate their close spacing.

Although in FIG. 2, only one funnel arrangement including funnel pins 60 and one set of center pins 80 is shown, it can easily be imagined that a funnel pin and center pin arrangement can be arranged for each particular hot spot that may exist on a base plate. Thus, the terminology “center pin” should not be construed to be limiting to a central location, as pins over a hot spot may be located anywhere on a base plate where a hot spot is located. It-should also be understood that funnel arrangements of pins may overlap each other, depending upon how closely hot spots are located relative to each other.

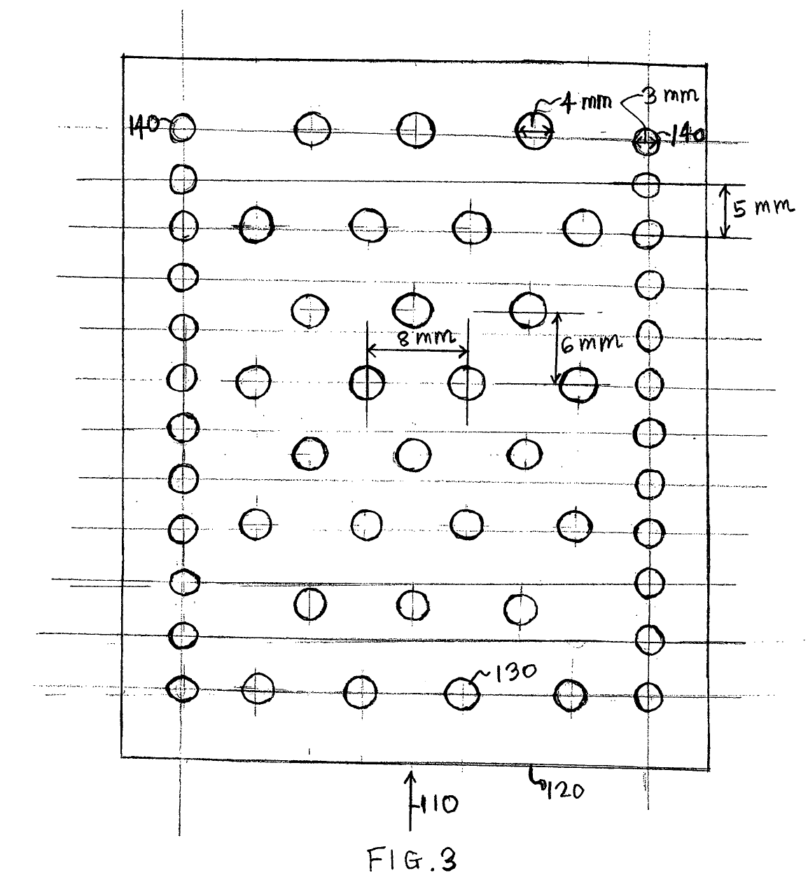

FIG. 3 shows a second embodiment of the invention. The second embodiment of the invention differs from the first embodiment of the invention in that there are no funnel pins and no center pins. This embodiment of the invention is adapted to be used, for example, when no hot spots are created by electronic or other heat generating devices beneath base plate 120. In such a case, pins 130 are arranged in a conventional staggered pin arrangement. However, guard pins 140 are arranged, as in the first embodiment, near to the edges of base plate 120 and parallel to the direction of air flow 110, so as to limit air leakage perpendicular to the direction of the air flow 110. As in the first embodiment of the invention, the guard pins 140 are of smaller diameter than the pins 130 located on the interior of the base plate 120, and are spaced closer together than are the pins 130.

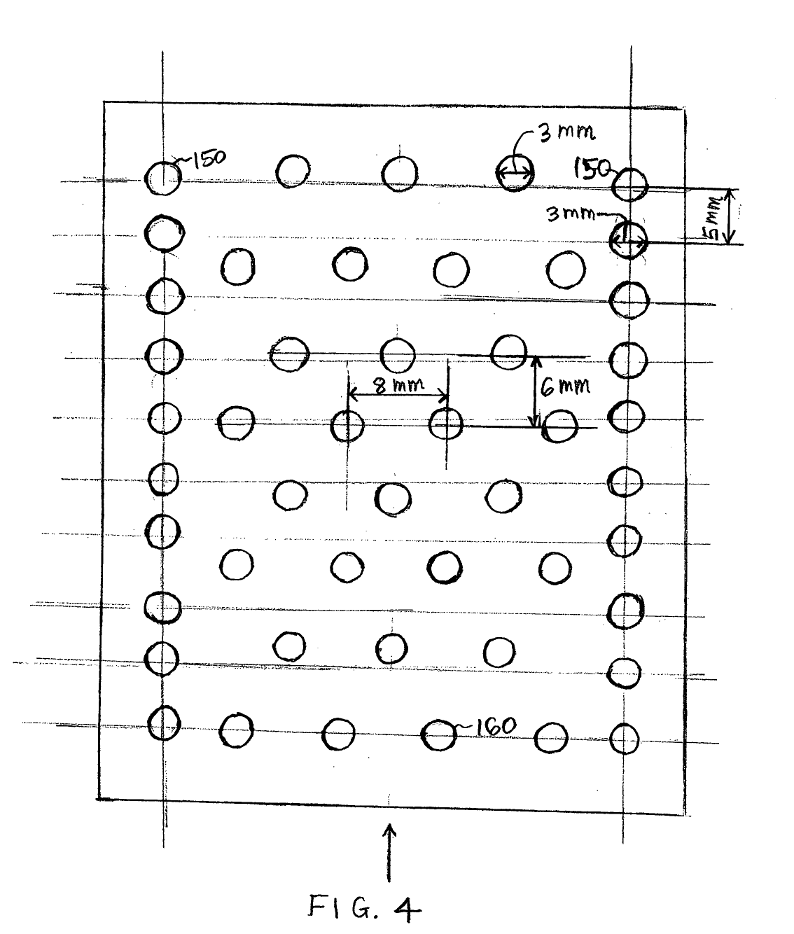

FIG. 4 shows a third embodiment of the invention. The only differences of the third embodiment of the invention from the second embodiment of the invention are that the guard pins 150 are of substantially the same size as the interior pins 160, which are in the conventional staggered pin arrangement as in the second embodiment of the invention, and that the interior pins 160 have been reduced in diameter, when compared to interior pins 130.

All dimensions shown in FIGS. 1, 2, 3, and 4 are exemplary only, and are not to be construed as limiting the present invention in any manner.

Although the heat sink elements are referred to herein as “pins,” no limitation on the shapes or sizes of the heat sink elements is intended.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A pin heat sink comprising
a base plate; and
pins arranged on said base plate, said pins comprising a first plurality of pins, arranged in such a manner as to create at least one funnel for guiding air flow towards at least one area of said base plate, and at least one second pin located in said at least one area of said base plate.

2. A pin heat sink of claim 1, further comprising a plurality of guard pins, arranged along two opposite edges of said base plate on opposite sides of said first plurality of pins and said at least one second pin for further guiding said air flow over said base plate.

3. A pin heat sink of claim 2, wherein said plurality of guard pins are of a smaller diameter than said first plurality of pins and said at least one second pin.

4. A pin heat sink of claim 2, wherein said plurality of guard pins are of substantially the same diameter as said first plurality of pins and said at least one second pin.

5. A pin heat sink of claim 1, further comprising a third plurality of pins arranged in rows on said base plate, such that pins in each row of pins are offset from pins in an adjacent row of pins in a direction parallel to said adjacent row.

6. A pin heat sink of claim 2, further comprising a third plurality of pins arranged in rows on said base plate, such that pins in each row of pins are offset from pins in an adjacent row of pins in a direction parallel to said adjacent row.

7. A pin heat sink of claim 6, wherein said plurality of guard pins are arranged on opposite sides of said third plurality of pins.

8. A pin heat sink of claim 6, wherein said plurality of guard pins are spaced closer together than said first plurality of pins, said at least one second pin, and said third plurality of pins.

9. A pin heat sink of claim 8, wherein said plurality of guard pins are arranged on opposite sides of said third plurality of pins.

10. A pin heat sink comprising
a base plate;
a first plurality of pins arranged on said base plate; and
a second plurality of pins spaced closer together than said first plurality of pins.

11. A pin heat sink of claim 10, wherein said second plurality of pins are arranged along opposite edges of said base plate on opposite sides of said first plurality of pins.

12. A pin heat sink of claim 11, wherein said second plurality of pins are of smaller diameter than said first plurality of pins.

13. A pin heat sink of claim 11, wherein said first plurality of pins are arranged in rows, such that pins in each row of pins are offset from pins in an adjacent row of pins in a direction parallel to said adjacent row.

14. A pin heat sink of claim 10, wherein said second plurality of pins are of smaller diameter than said first plurality of pins.

15. A pin heat sink of claim 14, wherein said first plurality of pins are arranged in rows, such that pins in each row of pins are offset from pins in an adjacent row of pins in a direction parallel to said adjacent row.

16. A pin heat sink of claim 10, wherein said second plurality of pins are of substantially the same diameter as said first plurality of pins.

17. A pin heat sink of claim 16, wherein said second plurality of pins are arranged along opposite edges of said base plate on opposite sides of said first plurality of pins.

18. A pin heat sink of claim 16, wherein said first plurality of pins are arranged in rows, such that pins in each row of pins are offset from pins in an adjacent row of pins in a direction parallel to said adjacent row.

19. A pin heat sink of claim 10, wherein said first plurality of pins are arranged in rows, such that pins in each row of pins are offset from pins in an adjacent row of pins in a direction parallel to said adjacent row.
